(19) United States
(12) Patent Application Publication
(10) Pub. No.: US 2016/0237303 A1
(43) Pub. Date: Aug. 18, 2016

(54) RESIN COMPOSITION FOR PRINTED CIRCUIT BOARD, INSULATING FILM, AND PRINTED CIRCUIT BOARD USING THE SAME

(71) Applicant: Samsung Electro-Mechanics Co., Ltd., Suwon-si (KR)

(72) Inventors: Geum-Hee YUN, Hwaseong-si (KR); Dae-Hui JO, Seoul (KR); Seong-Hyun YOO, Seongnam-si (KR); Keung-Jin SOHN, Suwon-si (KR); Jin-Young KIM, Suwon-si (KR)

(73) Assignee: Samsung Electro-Mechanics Co., Ltd., Suwon-si (KR)

(21) Appl. No.: 14/951,045

(22) Filed: Nov. 24, 2015

(30) Foreign Application Priority Data
Feb. 16, 2015 (KR) 10-2015-0023517

(51) Int. Cl. C09D 163/00; C09D 179/08; H05K 1/03

(52) U.S. Cl. CPC C09D 163/00; H05K 1/0353; C09D 179/08

(57) ABSTRACT

A resin composition for a printed circuit includes a first resin having a polycyclic group; a second resin having an imide group conjugated to at least one cyclic group; and a hardening accelerator having two or more functional groups, wherein the resin composition does not include a hardening agent.

### CROSS REFERENCE TO RELATED APPLICATION(S)

This application claims the benefit of Korean Patent Application No. 10-2015-0023517 filed on Feb. 16, 2015 in the Korean Intellectual Property Office, the entire disclosure of which is incorporated herein by for all purposes.

### BACKGROUND

1. Field

The following description relates to a resin composition for a printed circuit board, and an insulating film and a printed circuit board using the same.

2. Description of Related Art

In accordance with development of more compact electronic devices, printed circuit boards used in such devices have progressed to become lighter, thinner and generally smaller in size. In order to satisfy the demand for printed circuit boards that are light, thin and small in size, electrical, thermal, and dimensional properties required for a substrate function have become more important factors.

The printed circuit board includes copper mainly serving as a circuit wiring and a polymer resin serving as an interlayer insulation. In consideration of the demand for lighter, thinner and smaller printed circuit boards, insulation thickness of a prepreg and a copper clad laminate has become thinner and thinner. As the circuit board becomes thinner, the rigidity of the board itself decreases, causing defects due to a bending phenomenon at the time of mounting components thereon at a high temperature. Therefore, thermal expansion and heat resistance properties of a heat curable polymer resin function as important factors. That is, at the time of heat curing, the network between polymer chains forming a polymer structure, and a board composition and curing density are closely affected.

In KR Patent Publication No 2014-0080183, a resin composition for a printed circuit board including a hardening agent is disclosed.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

According to one general aspect, a resin composition for a printed circuit board includes a first resin having a polycyclic group; a second resin having an imide group conjugated to at least one cyclic group; and a hardening accelerator having two or more functional groups, wherein the resin composition does not include a hardening agent.

The hardening agent may include a phenolic hydroxyl group or a hydroxyl group.

The hardening agent may include two or more phenolic hydroxyl groups in one molecule.

The hardening agent may be one of diethylenetriamine, triethylenetetramine, bis(4-aminocyclohexyl)methane, isophorone diamine, 4,4-diamino-diphenylmethane) or methyltetrahydrophthalic anhydride.

The polycyclic group of the first resin may include at least one of a biphenyl group, a biphenyl novolak group, a naphthalene group, a naphthalene novolak group, an anthracene group, a dihydroanthracene group, or a triphenylene group.

The first resin may be an epoxy resin including two or more epoxy groups in one molecule.

The first resin may be a naphthalene-based epoxy resin or a phenyl novolak-based epoxy resin.

An amount of the first resin may be 30 to 70 wt % with respect to the resin composition.

An amount of the second resin may be 10 to 50 wt % with respect to the resin composition.

Impurities included in the first resin may be 750 ppm or less.

An amount of the hardening accelerator may be 0.5 to 4 phr with respect to the resin composition.

The resin composition may further include a cyanate ester resin.

An amount of the cyanate ester resin may be 50 wt % or less with respect to the resin composition.

The cyanate ester resin may be a phenol novolak-based cyanate resin or a biphenyl-based cyanate ester resin.

According to another general aspect, an insulating film is formed by using a resin composition for a printed circuit board including: a resin having a polycyclic group; a resin having an imide group conjugated to at least one cyclic group; and a hardening accelerator having two or more functional groups, wherein the resin composition does not include a hardening agent.

According to another general aspect, a printed circuit board includes an insulating film formed by using a resin composition, wherein the resin composition includes: a first resin having a polycyclic group; a second resin having an imide group conjugated to at least one cyclic group; and a hardening accelerator having two or more functional groups, wherein the resin composition does not include a hardening agent.

The hardening agent comprises a phenolic hydroxyl group or a hydroxyl group.

An amount of the first resin may be 30 to 70 wt % with respect to the resin composition, or an amount of the second resin may be 10 to 50 wt % with respect to the resin composition.

Other features and aspects will be apparent from the following detailed description, the drawings, and the claims.

### BRIEF DESCRIPTION OF THE DRAWINGS

FIG. 1 is a sectional view illustrating an example of a printed circuit board.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Resin Composition

A resin composition for a printed circuit board, according to an example, includes a first resin having a polycyclic group, a second resin having an imide group conjugated to at least one cyclic group, and a hardening accelerator having 2 or more functional groups, wherein a hardening agent is not included.

In general, as a printed circuit board becomes thinner, the rigidity of board itself decreases, causing defects due to a bending phenomenon at the time of mounting components thereon at a high temperature. Therefore, thermal expansion and heat-resistance properties of a heat curable polymer resin function as important factors. That is, at the time of heat curing, the network between polymer chains configuring a polymer structure, and a board composition and curing density are closely affected.

Each element in the resin composition, according to an example, interpenetrates to form interpenetrating polymer networks (IPNs). The resin composition according to an example therefore has a high glass transition temperature (Tg) and a low coefficient of thermal expansion such that warpage of the product may be prevented. Therefore, according to an example, the resin composition for a printed circuit board, an insulating film for the printed circuit board, and the printed circuit board manufactured by using the resin composition have high storage stability at room temperature and excellent workability.

In addition, an insulating layer, a prepreg and the like manufactured by using the resin composition according to an example has improved cross linking density, coefficient of thermal expansion and glass transition temperature due to interaction networks between compositions. Therefore, a resin composition for a printed circuit board having excellent thermal properties, an insulating layer for the printed circuit board and the printed circuit board manufactured by using the same may be provided.

First Resin—Resin Having a Polycyclic Group

A resin composition for a printed circuit board according to an example is advantageous to form an interpenetrating polymer network (IPN) structure, resulting in excellent thermal properties because the resin includes polycyclic groups.

According to an example, the resin composition includes a first resin having a polycyclic group. The polycyclic group may be at least one of a biphenyl group, a biphenyl novolak group, a naphthalene group, a naphthalene novolak group, an anthracene group, a dihydroanthracene group, or a triphenylene group.

The first resin may be a thermosetting resin having high flowability during heating and excellent heat-resistant property or dimensional stability after hardening. The first resin may be an epoxy resin including 2 or more epoxy groups in one molecule.

The first resin may be at least one epoxy compound selected from a bisphenol A-type epoxy resin, a bisphenol F-type epoxy resin, a bisphenol S-type epoxy resin, a phenol novolak-type epoxy resin, a cresol novolak-type epoxy resin, an alkylphenol novolak-type epoxy resin, a bisphenol-type epoxy resin, a naphthalene-based epoxy resin, a dicyclopentadiene type epoxy resin, a triglycidyl isocyanate, or an acyclic epoxy resin.

Particularly, examples of the first resin include YDCN-500-90P (o-cresol Novolac Type Epoxy Resin), YDPN-631 (Phenol Novolac Epoxy), and KDP-540, YH-300 (Tri-Functional Epoxy Resin) manufactured by Kukdo Chemicals, HP-4032 (Naphthalene type Epoxy resin), HP-4700 (Naphthalene type Epoxy resin), HP-4710 (Naphthalene type Epoxy resin), HP-4750 (Naphthalene type Epoxy resin), HP-4770 (Low viscosity Naphthalene type Epoxy resin), HP-5000 (Naphthalene backbone modified polyfunctional type Epoxy resin), HP-6000 (Naphthalene type Epoxy resin), and HP-7200 (Dicyclopentadiene type Epoxy resin) manufactured by DIC Corp. and NC-3000(low melt viscosity biphenyl type epoxy resin), NC-3000H (biphenyl type epoxy resin), NC-3000L (low melt viscosity biphenyl type epoxy resin), EPPN-501H (tri-functional novolac epoxy resin), and EPPN-502H (triphenylmethane epoxy resin) manufactured by Nippon Kayaku Corp.

When the naphthalene-based epoxy resin is used as the first resin, low thermal expansion may be improved. When the phenyl novolak-type epoxy resin is used as the resin having a polycyclic group, moldability may be improved.

Examples of the naphthalene-based epoxy resin include a 4-functional methane-typed naphthalene-based epoxy resin represented by the following Formula 1 and a 4-functional methane-typed naphthalene-based epoxy resin represented by the following Formulas 2 to 4.

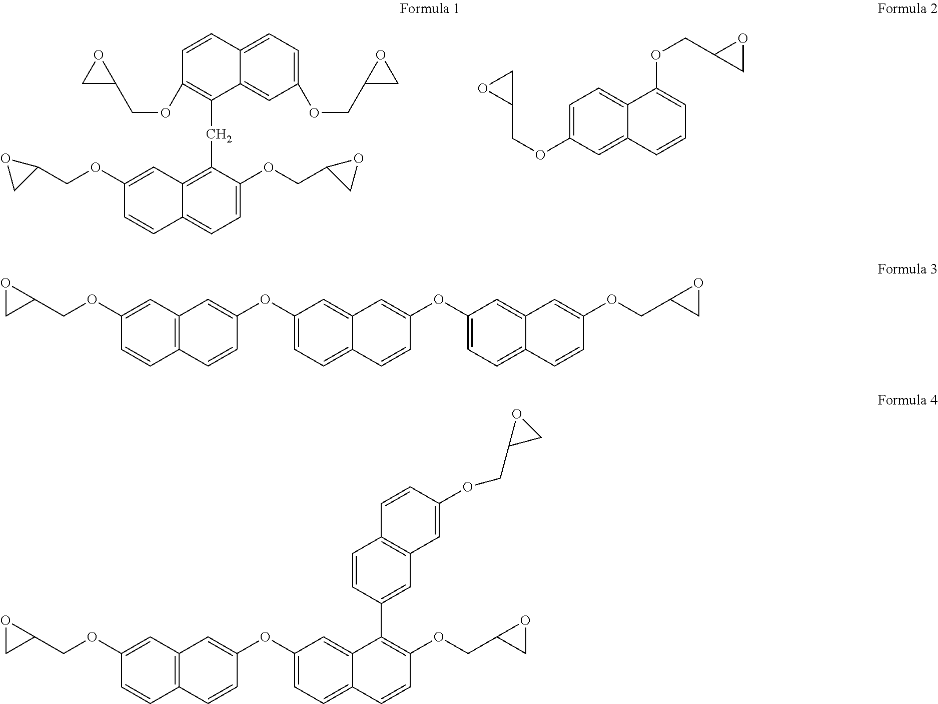 [SMILES: c1cc2ccc(OCC3CO3)c(Cc3c(OCC4CO4)ccc4ccc(OCC5CO5)cc34)c2cc1OCC1CO1 ; c1cc(OCC2CO2)c2ccc(OCC3CO3)cc2c1 ; c1cc2ccc(Oc3ccc4ccc(Oc5ccc6ccc(OCC7CO7)cc6c5)cc4c3)cc2cc1OCC1CO1 ; c1cc2ccc(Oc3ccc4ccc(OCC5CO5)c(-c5ccc6ccc(OCC7CO7)cc6c5)c4c3)cc2cc1OCC1CO1]

The phenyl novolak-based epoxy resin may be represented by the following formula 5.

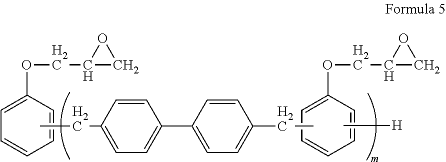

An amount of the first resin may be, for example, 30 to 70 wt % with respect to the resin composition for a printed circuit board. When the amount of the first resin is less than 30 wt %, the resin composition may not be hardened sufficiently or may be brittle, thereby causing difficulties in molding. On the other hand, when the amount of the first resin is more than 70 wt %, mechanical/thermal properties of the resin composition such as glass transition temperature (Tg) and modulus, thermal decomposition temperature (Td), peel strength with the copper film and the like may be deteriorated. Further, viscosity of the resin composition may be increased, such that difficulties in molding and processing may be caused.

An amount of impurities included in the first resin may be, for example, 750 ppm or less. When the amount of impurities included in the resin having a polycyclic group is more than 750 ppm, the cross linking density may be deteriorated since the impurities may disturb the formation of networks between the resins, such that moldability, storage stability and thermal properties may be decreased. The impurities included in the first resin may be, for example, hydrolysable chlorine.

Second Resin—Resin Having an Imide Group Conjugated to at Least One Cyclic Group

According to an example, the resin composition includes a second resin having an imide group conjugated to at least one cyclic group which may be advantageous to form interpenetrating polymer networks (IPNs) and provide good thermal properties.

According to an example, the second resin included in the resin composition may be a resin represented by the following Formulas 6 and 7.

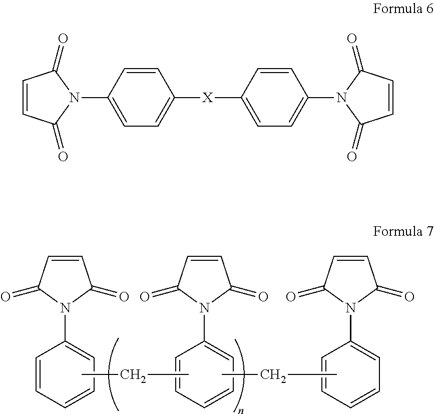

Examples of the second resin include BMI-100 (4,4′-diphenylmethane bismaleimide), BMI-2000, BMI-2300 (oligomer of phenyl methanemaleimide), BMI-3000 (m-phenyl enebismaleimide), BMI-4000 (bisphenol A diphenyl ether bismaleimide), BMI-5100 (3,3′-dimethyl-5,5′-diethyl-4,4′-diphenylmethanebismaleimide), BMI-7000 (4-methyl-1,3-phenylenebismaleimide), and BMI-TMH (1,6-bismaleimide-(2,2,4-trimethyl)hexane) manufactured by DAIWA Corp.

An amount of the second resin may be, for example, 10 to 50 wt % with respect to the resin composition for a printed circuit board. When the amount of the second resin is less than 10 wt %, thermal properties such as coefficient of thermal expansion (CTE) and glass transition temperature (Tg) may be decreased. On the other hand, when the amount of the second resin is more than 50 wt %, solubility of the resin composition, viscosity of a varnish and cross linking density of a mold may be decreased, thereby causing phase separation, forming a brittle resin composition, deteriorated peel strength with the copper film or difficulties in manufacturing molds.

Hardening Accelerator Having 2 or More Functional Groups

The resin composition according to an an example includes a hardening accelerator having 2 or more functional groups.

Examples of the hardening accelerator include 2MZ-A (2,4-diamino-6-[2′-methylimidazolyl-(1′)]-ethyl-s-triazine), 2E4MZ-BIS (4,4′-Methylenebis[2-ethyl-5-methylimidazole]), 2MZA-PW (2,4-diamino-6-[2′-methylimidazolyl-(1′)]-ethyl-s-triazine), C11Z-A (2,4-diamino-6-[2′-undecylimidazolyl-(1′)]-ethyl-s-triazine), 2E4MZ-A (2,4-diamino-6-[2′-ethyl-4′-methylimidazolyl-(1′)]-ethyl-s-triazine), 2MA-OK (2,4-diamino-6-[2′-methylimidazolyl-(1′)]-ethyl-s-triazineisocyanuric acid adduct dehydrate), and 2PZ-OK (2-phenylimidazoleisocyanuric acid adduct) manufactured by Shikoku.

An amount of the hardening accelerator may be, for example, 0.5 to 4 phr with respect to the resin composition. When the amount of the hardening accelerator is less than 0.5 phr, the resin composition may not be hardened sufficiently. On the other hand, when the amount of the hardening accelerator is more than 4 phr, the resin composition may be over-hardened, causing defects due to excess hardening accelerator.

Hardening Agent

According to an example, a hardening agent which is not included in the resin composition includes a phenolic hydroxyl group or a hydroxyl group. The hardening agent may be, for example, a phenol type resin having 2 or more phenolic hydroxyl groups in one molecule. When a hardening agent is added to the resin composition, it may form a gel in a short time due to poor stability. The resin composition including the hardening agent may therefore have deteriorated moldability and storage stability.

Thus, according to an example, the resin composition disclosed herein does not include the hardening agent, such that an abrupt hardening reaction is prevented at room temperature and the storage stability is improved. When a hardening agent including a phenolic hydroxyl group or a hydroxyl group is used, gelation of cyanate esters may be accelerated with hydroxyl groups of the hardening agent, causing significant deterioration of the storage stability of a varnish. However, since the example resin composition disclosed herein does not include a hardening agent including a phenolic hydroxyl group, such problems are eliminated.

According to an example, the hardening agent is an amine without any hydroxyl group or a cyclic anhydrous hardening agent. For example, the hardening agent may be at least one of diethylenetriamine, triethylenetetramine (TETA), bis(4-aminocyclohexyl)methane (PACM), isophorone diamine (IPDA), 4,4-diamino-diphenylmethane (DDM) or methyltetrahydrophthalic anhydride (MTH PA).

Third Resin—Cyanate Ester Resin

According to an example, the resin composition further includes a third resin, which is a cyanate ester resin. When the cyanate ester resin is used, thermal properties such as coefficient of thermal expansion (CTE) and glass transition temperature (Tg) may be improved and a varnish with low viscosity may be provided. Furthermore, an inorganic material such as silica may be easily filled.

The cyanate ester resin may be, for example, a phenol novolak-based cyanate resin or a biphenyl-based cyanate ester resin. The phenol novolak-based cyanate resin may be represented by the following Formula 8 and the biphenyl-based cyanate ester resin may be represented by the following Formula 9.

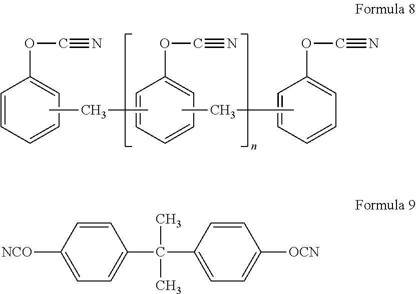

An amount of the cyanate ester resin may be, for example, 50 wt % or less with respect to the resin composition. When the amount of the cyanate ester resin is more than 50 wt %, thermal/mechanical properties may be deteriorated and the resin composition may not be hardened sufficiently. It may further increase a hardening temperature of the resin composition and deteriorate moldability.

Solvent

A solvent to dissolve the resin composition may be a commonly used solvent and it is not limited to a particular type of solvent. For example, a gel time may be used for the moldability and methyl ethyl ketone, PGMEA, cyclohexanone or a solvent having a polarity similar thereto may be used for the storage stability.

### EXAMPLE

Each amount of a hydroxyl group and impurities of the first resin (resin having a polycyclic group), gel time depending on an amount of the hardening agent, and shelf-life are summarized in the following Table 1. The resin composition for a printed circuit board according to an embodiment the above disclosure was used for Examples 1 and 2 in Table 1, and the resin composition in which one of conditions for the resin composition was deviated was used for Comparative Examples 1-4.

The first resin was HP-4710 manufactured by DIC Corp., the second resin (resin having an imide group conjugated to at least one cyclic group) was BMI-2300 manufactured by DAIWA Corp., the hardening accelerator was 2MZ-A manufactured by Shikoku Corp., and the third resin (cyanate ester resin) was PT-30 manufactured by Lonza Corp. The hardening agent was TPM (KPH-3100, HEW 100). 1 wt % of the hardening accelerator was used.

Samples were dried for 2 hours at room temperature and for 3 hours in a vacuum oven to remove a solvent completely and then a gel time was determined at 170° C. using a timer. Shelf-life of samples was determined with naked eyes.

TABLE 1

| | Amount of | Amount of | | |
|---|---|---|---|---|
| | impurities in | the hardening | | |
| | epoxy | agent | Gel time | Shelf-life |
| Sample No. | (ppm) | (wt %) | (sec) | (hr) |
| Example 1 | 200 | 0 | 116 | 168 |
| Example 2 | 750 | 0 | 74 | 120 |
| Comparative | 1000 | 0 | 35 | 72 |
| Example 1 | | | | |
| Comparative | 200 | 25 | 339 | 16 |
| Example 2 | | | | |
| Comparative | 750 | 25 | 198 | 5 |
| Example 3 | | | | |
| Comparative | 1000 | 25 | 152 | 2 |
| Example 4 | | | | |

Referring to Table 1, the shelf-life of Comparative Examples 2-4 which included the hardening agent was 2 to 16 hours, which shows poor storage stability. Gel time of Comparative Example 1 in which the amount of impurities in epoxy was 1000 ppm was 35 seconds, which shows rapid gelation, causing poor moldability, workability, and thermal properties.

Insulating Film

An insulating film according to an example was prepared by using the resin composition for a printed circuit board including the first resin (resin having a polycyclic group), the second resin (resin having an imide group conjugated to at least one cyclic group) and a hardening accelerator having 2 or more functional groups but not including a hardening agent.

A method for preparing the insulating film is not particularly limited and any known method can be used.

The insulating film was prepared by the following method. Silica inorganic filler powder 3 Kg was dispersed into a methyl ethyl ketone (MEK) solvent 750 g to provide a filler slurry including 80% solid content. A dispersing agent (BYK-337, 1.0% with respect to the filler) and a silane coupling agent (GPTMS, 2.0% with respect to the filler) were added to the filler slurry. A resin having an imide group conjugated to at least one cyclic group and a resin having a polycyclic group were added to the filler slurry and the mixed slurry was stirred for 2 hours. A cyanate ester resin was further added to the mixed slurry and stirred for 1 hour. 2E4MZ as a hardening catalyst and Mn2AA as a metal catalyst were added and stirred for over 30 minutes to provide a complete solution. The resulting dissolved varnish was coated on a copper foil in a constant thickness and half-hardened at a temperature range of 80˜140° C. The varnish coated on the copper foil was further thermally compressed at 230° C. using a vacuum press to provide an insulating film.

When an insulating film which does not include the cyanate ester resin was prepared, it was prepared by the above-described method, except that the cyanate ester resin was not added. An inorganic filler was added to an oligomer solution including a liquid crystal oligomer and the mixed solution was stirred. An epoxy resin was added and the mixed solution was stirred. A hardening agent was additionally added and the mixed solution was stirred and dried in an oven at about 100° C. to provide an insulating film. If needed, other additives may be added and the mixed solution may be coated on a copper foil or another insulating layer and then dried in an oven. The same explanations provided above for the resin composition are omitted.

Printed Circuit Board

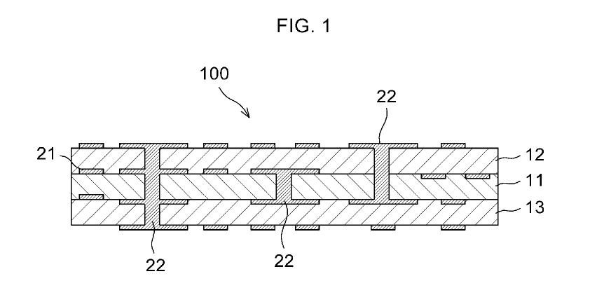

FIG. 1 is a sectional view illustrating a printed circuit board 100 according to an example.

Referring to FIG. 1, the printed circuit board 100 includes insulating films 11, 12, 13 prepared by using the resin composition including the first resin (resin having a polycyclic group), the second resin (resin having an imide group conjugated to at least one cyclic group) and a hardening accelerator having 2 or more functional groups, but not including a hardening agent.

The explanations for the resin composition provided above are omitted.

A horizontal wire 21 is disposed on one surface (e.g., a top or bottom surface) or both surfaces of the insulating films 11, 12, 13 and a via electrode 22 vertically passes through the insulating films 11, 12, 13 to electrically connect each horizontal wire 21. A 4-layer printed circuit board is shown in FIG. 1, but the disclosure is not limited thereto. A single layer or 2-or more-layered circuit board may be formed based on the number of the insulating films and circuit patterns to be formed.

The insulating films 11, 12, 13 are prepared, for example, by using the one of the resin compositions in Examples 1 and 2 of Table 1.

A copper foil layer may be formed on at least one surface of the insulating film 11, 12, 13 and the horizontal wire 21 may be formed by eliminating a part of the copper foil layer. One or more via holes may be formed on one surface of the insulating film 11, 12, 13 prior to forming the copper foil layer and a conductive material may be filled in the via hole(s) to form the via electrode(s) 22. The insulating film 11, 12, 13 may be stacked on the upper part of another insulating film 11, 12, 13 on which the horizontal wire 21 is formed and the copper foil layer may be formed repeatedly. The printed circuit board 100 may include a capacitor, a resistor or other electronic components if needed. A solder resist layer (not shown) may be formed at the outermost layer to protect the circuit board. An externally connecting unit or a pad layer (not shown) may be formed on the printed circuit board 100 based on electronics to be mounted.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

### DESCRIPTION OF REFERENCE NUMERALS

100: Printed circuit board

11, 12, 13: Insulating film

21: Horizontal wire

22: Via electrode

What is claimed is:

1. A resin composition for a printed circuit board, the resin composition comprising:
a first resin comprising a polycyclic group;
a second resin comprising an imide group conjugated to at least one cyclic group; and
a hardening accelerator comprising two or more functional groups,
wherein the resin composition does not include a hardening agent.

2. The resin composition of claim 1, wherein the hardening agent comprises a phenolic hydroxyl group or a hydroxyl group.

3. The resin composition of claim 1, wherein the hardening agent comprises two or more phenolic hydroxyl groups in one molecule.

4. The resin composition of claim 1, wherein the hardening agent is one of diethylenetriamine, triethylenetetramine, bis(4-aminocyclohexyl)methane, isophorone diamine, 4,4-diamino-diphenylmethane) or methyltetrahydrophthalic anhydride.

5. The resin composition of claim 1, wherein the polycyclic group of the first resin comprises at least one of a biphenyl group, a biphenyl novolak group, a naphthalene group, a naphthalene novolak group, an anthracene group, a dihydroanthracene group, or a triphenylene group.

6. The resin composition of claim 1, wherein the first resin is an epoxy resin comprising two or more epoxy groups in one molecule.

7. The resin composition of claim 1, wherein the first resin is a naphthalene-based epoxy resin or a phenyl novolak-based epoxy resin.

8. The resin composition of claim 1, wherein an amount of the first resin is 30 to 70 wt % with respect to the resin composition.

9. The resin composition of claim 1, wherein an amount of the second resin is 10 to 50 wt % with respect to the resin composition.

10. The resin composition of claim 1, wherein impurities included in the first resin is 750 ppm or less.

11. The resin composition of claim 1, wherein an amount of the hardening accelerator is 0.5 to 4 phr with respect to the resin composition.

12. The resin composition of claim 1, further comprising a cyanate ester resin.

13. The resin composition of claim 12, wherein an amount of the cyanate ester resin is 50 wt % or less with respect to the resin composition.

14. The resin composition of claim 12, wherein the cyanate ester resin is a phenol novolak-based cyanate resin or a biphenyl-based cyanate ester resin.

15. An insulating film for a printed circuit board, the insulating film being formed using a resin composition comprising:
a resin comprising a polycyclic group;
a resin comp rising an imide group conjugated to at least one cyclic group; and
a hardening accelerator comprising two or more functional groups,
wherein the resin composition does not include a hardening agent.

16. A printed circuit board comprising an insulating film formed by using a resin composition for a printed circuit board, wherein the resin composition comprises:
a resin comprising a polycyclic group;
a resin comprising an imide group conjugated to at least one cyclic group; and
a hardening accelerator having two or more functional groups,
wherein the resin composition does not include a hardening agent.

17. The printed circuit board of claim 16, wherein the hardening agent comprises a phenolic hydroxyl group or a hydroxyl group.

18. The printed circuit board of claim 16, wherein:
an amount of the first resin is 30 to 70 wt % with respect to the resin composition; or
an amount of the second resin is 10 to 50 wt % with respect to the resin composition.
